(19) United States
(12) Patent Application Publication
(10) Pub. No.: US 2006/0141666 A1
(43) Pub. Date: Jun. 29, 2006

(54) Method for producing a module including an integrated circuit on a substrate and an integrated module manufactured thereby

(75) Inventors: Andre Hanke, Strausberg (DE); Michael Dunkel, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/024,237

(22) Filed: Dec. 29, 2004

(51) Int. Cl. H01L 21/50; H01L 21/44

(52) U.S. Cl. 438/106; 438/119; 438/612

(57) ABSTRACT

The present invention relates to a method for producing a module including an integrated circuit die on a substrate. A substrate is provided, a metallization structure is provided which includes a conductive path and a metallization contact pad on the substrate. The integrated circuit die is placed onto the substrate, such that an integrated contact pad of the integrated circuit is positioned in close proximity to the metallization contact pad, and a conductive paste is selectively applied such that a conductive connection is formed between the integrated contact pad and the metallization contact pad.

### TECHNICAL FIELD OF THE INVENTION

The present invention relates to a method for producing a module including an integrated circuit die on a substrate, and to an integrated module comprising an integrated circuit die placed on a substrate.

### BACKGROUND OF THE INVENTION

The manufacturing of a multi-chip module and packages, where an integrated circuit die (chip) is attached to a substrate in order to provide a package for an integrated circuit, is usually performed by placing the die onto the substrate and bonding integrated contact pads arranged on the die to associated contact pads arranged on the substrate by a Flip-Chip-technique and such like. While the Flip-Chip-technique is expensive as it suffers from a low yield, the place-and-bond-technique has a low throughput in an automatic production line as the integrated contact pads on the die and the substrate have to be interconnected with a bond wire in a serial manner so that such a manufacturing of a MCM or of an integrated die package requires an essential time.

### SUMMARY OF THE INVENTION

The present invention discloses producing an integrated module, such as an multi-chip module or an integrated die package, with an increased yield and reduced costs.

Additionally, the present invention discloses a method for producing an integrated module using conventional process steps.

According to a first embodiment of the present invention, there is a method for producing a module including an integrated circuit die on a substrate. The method includes the providing a substrate; providing a metallization layer including a conductive path and a metallization contact pad on the substrate; placing the integrated circuit die onto the substrate, such that an integrated contact pad of the integrated circuit die is positioned in close proximity to the metallization contact pad on the substrate, and selectively applying a conductive paste such that a conductive connection is formed between the integrated contact pad and the metallization contact pad.

According to another embodiment of the present invention, the conductive paste is provided as a solder paste wherein after selectively applying the solder paste a reflow process is performed wherein the solder paste is melted and the conductive connection is formed.

Preferably, the solder paste is applied by means of a printing process, especially of a screen printing process.

According to still another embodiment of the present invention, the integrated circuit die is thinned before placing onto the substrate to provide a levelling of a metallization contact pad of the metallization layer and the integrated contact pad of the integrated circuit die.

Commonly, it can be provided that the metallization structure is provided with a thickness to provide the same height level of the upper surface of the integrated contact pad and the metallization contact pad.

Preferably, the integrated circuit, thinned or unthinned, is placed into a recess on the substrate.

Preferably, the recess is formed in an insulating layer by one of a printing process, a curtain coating process and a laminating process for laminating a structured solder stop foil onto the substrate.

Furthermore, it can be provided that the integrated circuit die is attached on the substrate by means of at least one of a glue and a mechanical fixing.

According to yet another embodiment of the present invention, an integrated module is provided comprising an integrated circuit die having an integrated contact pad to provide a contacting to the integrated circuit, a substrate on which the integrated circuit die is placed, a metallization structure provided on the substrate and including a conductive path and a metallization contact pad, wherein the integrated contact pad of the integrated circuit die is positioned in close proximity to the metallization contact pad, and a conductive paste which is applied to the integrated contact pad and the metallization contact pad, such that a conductive connection is provided between the integrated contact pad and the metallization contact pad.

Preferably, the metallization layer is formed with a thickness to provide a same high level of the upper surface of the integrated contact pad and the metallization contact pad.

Furthermore, it can be provided that the integrated circuit die is placed in a recess of the substrate.

According to a preferred embodiment of the present invention, the metallization comprises a structured metal layer deposited on the substrate.

### BRIEF DESCRIPTION OF THE DRAWINGS

The invention is described below in more detail with reference to the exemplary embodiments illustrated in the drawings, in which:

FIGS. 1a-1e show processing states for producing an integrated module according to a first embodiment of the present invention.

FIGS. 2a-2e show processing states of an integrated module according to a second embodiment of the present invention.

### DETAILED DESCRIPTION OF THE INVENTION

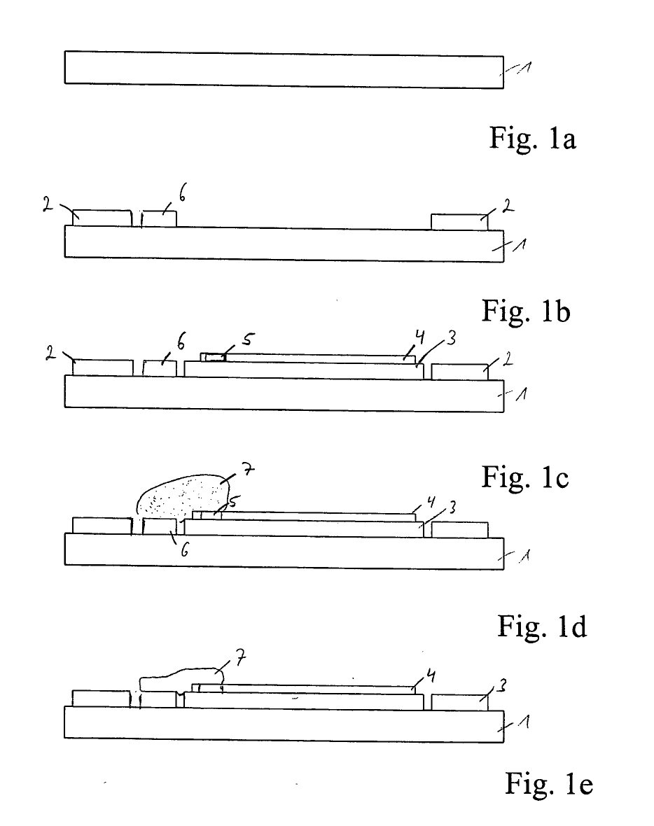

FIGS. 1a to 1e show the processing states of the manufacturing process for producing an integrated module comprising an integrated circuit die on a substrate 1. Such integrated modules are known as multi-chip modules (MCM), wherein a number of integrated circuit dies are attached and connected to a common substrate including an interconnection layer to provide an electronic system module. As integrated modules also device packages can be provided including a substrate on which an integrated circuit die is attached and connected via a redistribution layer provided on/in the substrate. Such packages are commonly known as ball grid arrays, pin grid arrays, Flip-Chip-Packages and variants thereof.

As shown in FIG. 1a, a substrate 1 is provided which usually serves as a support to carry and to protect an integrated circuit die to be attached thereon. Furthermore, particularly in the case of the multi-chip module or a device package, the substrate can include one or more redistribution layers to provide interconnections between the number of integrated circuit dies and/or between one integrated circuit die and a number of contact ports (e.g. solder bumps, pins) of the substrate. For ease of representation, the redistribution layer is not depicted in the figures. The substrate 1 can be made of a resin, a ceramic and any other insulating material adapted to be used as a substrate for integrated circuit dies.

As a next step, as shown in FIG. 1b, a structured metallization layer 2 is deposited onto a surface of the substrate 1. The metallization structure is formed by depositing a metal layer usually including materials such as aluminum, copper and/or other suitable materials having a low resistivity and being able to be deposited by commonly known processes. For example, the metallization layer 2 can be provided by sputtering, electroplating, laminating of a structured or non-structured metal foil and such like.

The metallization layer 2 is structured with known processes of lithography and etching to form conductive paths and contact pads (areas) to be interconnected with corresponding contact pads on the integrated circuit die and to define a position for placing the integrated circuit die 3.

As shown in FIG. 1c, an integrated circuit die 3 is placed on the substrate 1. The metallization layer 2 is structured so that the position on the substrate 1 on which the integrated circuit die 3 is to be positioned carries no metal structures to allow the integrated circuit die 3 to be placed on the surface of the substrate 1. The integrated circuit die 3 includes an integrated circuit providing an electronic and/or other functions and on which integrated contact pads 5 are provided. The integrated contact pads 5 are in connection with the integrated circuit usually by means of a rewiring layer 4 wherein the integrated contact pads 5 are arranged close to the edges of the integrated circuit die 3.

The integrated circuit die 3, the integrated contact pads 5 of the integrated circuit die 3, and the metallization contact pads of the substrate 1 are arranged in close proximity and preferably with their upper surface on the same height level so that the gap between the contact pads 5, 6 and the mismatch in height between the contact pads becomes small. The distance between the integrated contact pads 5 and the metallization contact pads 6 is made small to allow the applying of a conduction paste onto their respective upper surfaces and between them without causing unwanted electrical interconnections to other contact pads and conductive paths.

In a next step, as shown in the state of FIG. 1d, the conductive paste is screen printed onto the arrangement as shown in FIG. 1c, so that the conductive paste is selectively deposited as a strip or a trace extending from the integrated contact pad 5 on the integrated circuit die 3 to the metallization contact pad 6 on the substrate 1.

The conductive paste 7 can be made of a solder paste or any other paste including a conductive material. The conductive paste is deposited e.g. using a screen printing process. This can be performed by applying a mask onto the surface of the arrangement of FIG. 1c and applying the conductive paste 7 onto the mask and removing the mask, such that the conductive paste 7 remains on the positions of the surface of the arrangement of FIG. 1c, defined by the apertures of the mask

In order to provide a reliable conductive interconnection between the integrated contact pad of the integrated circuit die and the metallization contact pad of the metallization layer of the substrate, the conductive paste is cured or molten in a process for hardening the conductive paste and to obtain a reliable contacting of the conductive paste with the contact pads. In case of a solder paste, a reflow process is applied in which the solder paste is heated so that it melts and provides a solder path between the integrated contact pad 5 and the metallization contact pad 6. Of course, in the same manner interconnections between a larger number of metallization contact pads 6 and/or a number of integrated contact pads 5 can be formed.

To equalize the height levels of the integrated contact pad 5 and the metallization contact pad 6, it can be provided that before placing the integrated circuit die 3 onto the substrate 1, the integrated circuit die is thinned by an abrasive method applied to the backside of the integrated circuit die 3 such as a CMP process (chemical mechanical polishing). For example, the integrated circuit die 3 can be rendered as thin as about 75 μm. Furthermore, it can be provided that the metallization layer 2 is rendered thicker by repeating the step of depositing the metallization layer 2 onto the surface of the substrate 1 for a number of times.

In the reflow process, the molten solder does not diverge on the surface of the arrangement due to the surface tension of the solder. After solidifying of the solder as shown in FIG. 1e, the lateral structures applied to it before the screen printing are substantially maintained and provide a secure contacting of the integrated contact pads 5 and the metallization contact pads 6. As the distance between the contact pads 5, 6 is made small a conductive solder path between them is established.

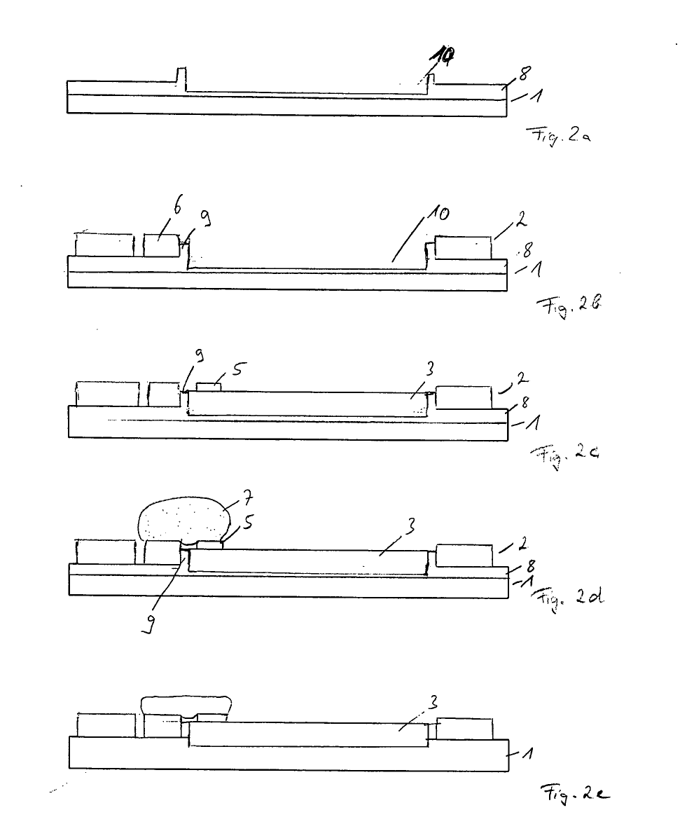

In the FIGS. 2a to 2e, process stages of the method for manufacturing an integrated module according to a second embodiment of the present invention is depicted. Elements with the same or a similar function are referenced with the same reference signs.

The manufacturing process of the second embodiment differs from the embodiment shown with regard to the FIGS. 1a to 1e in that the substrate 1 is provided with a recess 10 adapted to incorporate the integrated circuit die 3 wherein the depth of the recess, the thickness of the integrated circuit die 3 and the height of the metallization layer 2 on top of the surface of the substrate 1 are adapted to provide an equal level of the surfaces of the contact pads 5, 6. The recess 10 in the substrate 1 can be formed by conventional processes into the substrate 1, such as lithography and etch processes.

Furthermore, it can be provided that an insulating layer, e.g. a stop resist 8 for soldering is applied onto the surface of the substrate 1 structured to define the recesses 10 for placing the integrated circuit die 3 therein wherein the metallization layer 2 and the integrated circuit die 3 are embedded on/in the stop resist 8. The resulting gap 9 between the edge of the integrated circuit die 3 and the sidewalls of the metallization contact pads 6 of the metallization layer 2 is thereby filled with stop resist 8 for soldering so that no solder can intrude into the gap 9, thereby avoiding the formation of unwanted interconnections. The structuring of the stop resist 8 can be produced by a plane screen printing process with a thickness of the stop resist of 20, μm by a curtain coating with a thickness of the stop resist of 40 μm, or by laminating a soldering stop resist foil with a thickness of 50 μm to 100 μm.

In the embodiments, it is preferred to provide a glue (not shown) or mechanical fixing for securing the integrated circuit die 3 onto the substrate 1 so that no accidental shifting or unwanted moving of the integrated circuit die 3 on the substrate 1 occurs while the subsequent screen printing of the conductive paste is performed. The process of screen printing the interconnections between the integrated contact pads and the metallization contact pads make the bonding of the integrated circuit die obsolete and thereby allow to increase the yield of the manufacturing of integrated modules and to reduce the manufacturing costs.

What is claimed is:

1. A method for producing a module including an integrated circuit die on a substrate, comprising:
providing a substrate;
providing a metallization layer including a conductive path and a metallization contact pad on the substrate;
placing the integrated circuit die onto the substrate, such that an integrated contact pad of the integrated circuit die is positioned in close proximity to the metallization contact pad; and
selectively applying a conductive paste which is adapted to form a conductive connection between the integrated contact pad and the metallization contact pad.

2. The method according to claim 1, wherein the conductive paste is provided as a solder paste wherein after selectively applying the solder paste a reflow process is performed wherein the solder paste is melted and the conductive connection is formed.

3. The method according to claim 2, wherein the solder paste is applied by means of a printing process.

4. The method according to claim 1, wherein the integrated circuit die is thinned before placing onto the substrate.

5. The method according to claim 4, wherein the metallization layer is provided with a thickness to provide a same height level of the upper surface of the integrated contact pad and the metallization contact pad.

6. The method according to claim 5, wherein the integrated circuit die is placed into a recess on the substrate.

7. The method according to claim 6, wherein the recess is formed by one of a printing process, a curtain coating process and a laminating process for laminating a structured solder stop foil onto the substrate.

8. The method according to claim 1, wherein the integrated circuit die is attached on the substrate by means of at least one of a glue and a mechanical fixing.

9. An integrated module, comprising:
an integrated circuit die having a integrated contact pad to provide a contacting to the integrated circuit;
a substrate on which the integrated circuit die is placed;
a metallization layer provided on the substrate and including a conductive path and a metallization contact pad, wherein the integrated contact pad of the integrated circuit die is positioned in close proximity to the metallization contact pad; and
a conductive paste structure which is applied to integrated contact pad and the metallization contact pad, such that a conductive connection is provided between the integrated contact pad and the metallization contact pad.

10. The integrated module according to claim 9, wherein the metallization layer is formed with a thickness to provide a same height level of the upper surface of the integrated contact pad and the metallization contact pad.

11. The integrated module according to claim 10, wherein the integrated circuit die is placed in a recess of the substrate.

12. The integrated module according to claim 9, wherein the metallization layer comprises a structured metal layer deposited on the substrate.
